(19) United States
(12) Patent Application Publication
(10) Pub. No.: US 2017/0186591 A1
(43) Pub. Date: Jun. 29, 2017

(54) CLEANING METHOD OF PLASMA PROCESSING APPARATUS AND PLASMA PROCESSING APPARATUS

(71) Applicant: Tokyo Electron Limited, Tokyo (JP)

(72) Inventors: Kyosuke Hayashi, Kurokawa-gun, Miyagi (JP); Masayuki Sawataishi, Kurokawa-gun, Miyagi (JP)

(73) Assignee: Tokyo Electron Limited, Tokyo (JP)

(21) Appl. No.: 15/115,977

(22) PCT Filed: Feb. 17, 2015
(86) PCT No.: PCT/JP2015/000713

§ 371 Date: Aug. 2, 2016

(30) Foreign Application Priority Data
Mar. 4, 2014 (JP) 2014-041911

(51) Int. Cl. H01J 37/32; B08B 7/00

(52) U.S. Cl. CPC H01J 37/32669; H01J 37/32568; H01J 37/32091; H01J 37/32862; B08B 7/0035

(57) ABSTRACT

A deposit deposited on an upper electrode of a plasma processing apparatus having an electromagnet, which is provided on an upper portion of a processing chamber and includes concentrically arranged annular coils, can be removed by performing a cleaning method of the plasma processing apparatus. The cleaning method of the plasma processing apparatus includes introducing a preset cleaning gas into the processing chamber and generating plasma of the preset cleaning gas by applying a high frequency power between the upper electrode and a lower electrode; and generating a magnetic field by supplying electric currents to the coils, and adjusting an amount of the electric current supplied to each of the coils individually depending on a distribution of a thickness of the deposit deposited on the upper electrode in a radial direction thereof.

### TECHNICAL FIELD

The various embodiments described herein pertain generally to a cleaning method of a plasma processing apparatus and the plasma processing apparatus.

### BACKGROUND ART

Conventionally, in a manufacturing process of a semiconductor device, there is employed a plasma processing apparatus configured to generate plasma from a gas and perform an etching process or the like on a processing target substrate (e.g., a semiconductor wafer) with the generated plasma. As such a plasma processing apparatus, there is known a so-called capacitively coupled plasma processing apparatus in which an upper electrode and a lower electrode are disposed to face each other within a processing chamber, and the plasma is generated by applying a high frequency power between the upper electrode and the lower electrode. Further, there is also known a technique of controlling a plasma density by using a magnetic field in the plasma processing apparatus having such a configuration (see, for example, Patent Document 1).

In this plasma processing apparatus, if a plasma process such as plasma etching is performed repeatedly, a deposit such as polymer may be deposited within the processing chamber, so that an adverse effect may be caused on the plasma process. For this reason, a cleaning process of removing the deposit within the processing chamber is performed periodically. As such a cleaning method, there is known a method of removing the deposit by generating plasma of a cleaning gas within the processing chamber (see, for example, Patent Document 2).

Patent Document 1: Japanese Patent Laid-open Publication No. 2013-149722

Patent Document 2: Japanese Patent Laid-open Publication No. 2009-099858

### DISCLOSURE OF THE INVENTION

### Problems to be Solved by the Invention

In the conventional plasma processing apparatus as described above, the inside of the processing chamber is cleaned to remove the deposit such as the polymer. Recently, since miniaturization and high integration of semiconductor devices such as memory is approaching the limit, a 3D NAND memory in which a capacity thereof is increased by being stacked is becoming a mainstream. As for such a 3D NAND memory, though the capacity of the memory can be enhanced by increasing the stacking number, a processing time of the plasma etching also increases with the increase of the stacking number. As a result, a large amount of deposit may be deposited within the processing chamber. Therefore, the aforementioned cleaning process needs to be performed frequently. In this regard, it has been required to develop a method of conducting the cleaning process efficiently in a short period of time.

For example, in the capacitively coupled plasma processing apparatus in which the upper electrode and the lower electrode are disposed within the processing chamber to face each other, the thickness (amount) of the deposit deposited on the upper electrode may become non-uniform depending on, e.g., a distribution of a plasma density in the plasma process. In such a case, if it is attempted to remove a thick deposit portion on which a thickness of the deposit is large, a thin deposit portion on which a thickness of the deposit is small is continuously cleaned even after the deposit on the thin deposit portion is removed. As a result, the upper electrode is etched to be consumed.

In view of the foregoing, exemplary embodiments provide a cleaning method of a plasma processing apparatus and the plasma processing apparatus capable of suppressing consumption of an upper electrode when performing a cleaning process and capable of improving production efficiency by performing the cleaning process efficiently in a short period of time as compared to the conventional cases.

### Means for Solving the Problems

In one exemplary embodiment, there is provided a cleaning method of a plasma processing apparatus. Here, the plasma processing apparatus includes a processing chamber configured to accommodate a processing target substrate therein; a lower electrode provided within the processing chamber and configured to mount the processing target substrate thereon; an upper electrode, provided within the processing chamber, facing the lower electrode; a high frequency power supply configured to apply a high frequency power between the upper electrode and the lower electrode; and an electromagnet, provided on an upper portion of the processing chamber, including concentrically arranged annular coils. Further, the cleaning method, in which a deposit deposited on the upper electrode of the plasma processing apparatus is removed, includes introducing a preset cleaning gas into the processing chamber and generating plasma of the preset cleaning gas by applying the high frequency power between the upper electrode and the lower electrode from the high frequency power supply; and generating a magnetic field by supplying electric currents to the coils, and adjusting an amount of the electric current supplied to each of the coils individually depending on a distribution of a thickness of the deposit deposited on the upper electrode in a radial direction thereof.

In another exemplary embodiment, there is provided a plasma processing apparatus configured to process a processing target substrate with plasma. Here, the plasma processing apparatus includes a processing chamber configured to accommodate the processing target substrate therein; a lower electrode provided within the processing chamber and configured to mount the processing target object thereon; an upper electrode, provided within the processing chamber, facing the upper electrode; a high frequency power supply configured to apply a high frequency power between the upper electrode and the lower electrode; an electromagnet, provided on an upper portion of the processing chamber, including concentrically arranged annular coils; and a controller configured to, when performing a cleaning process of removing a deposit deposited on the upper electrode, introduce a preset cleaning gas into the processing chamber; generate plasma of the preset cleaning gas by applying the high frequency power between the upper electrode and the lower electrode from the high frequency power supply; generate a magnetic field by supplying electric currents to the coils; and adjust an amount of the electric current supplied to each of the coils individually depending on a distribution of a thickness of a deposit deposited on the upper electrode in a radial direction thereof.

### Effect of the Invention

According to the exemplary embodiments, consumption of the upper electrode when performing the cleaning process can be suppressed, and the cleaning process can be performed efficiently in a short period of time, as compare to the conventional cases. Therefore, the production efficiency can be improved.

### BRIEF DESCRIPTION OF THE DRAWINGS

FIG. 1 is a diagram schematically illustrating a configuration of a plasma etching apparatus according to an exemplary embodiment.

FIG. 2 is a diagram schematically illustrating a configuration of major components of the plasma etching apparatus of FIG. 1.

FIG. 3A to FIG. 3D are diagrams showing examples of a magnetic field generated by an electromagnet.

FIG. 4 is a graph showing an example of a thickness distribution of deposits on an upper electrode and a cover ring.

FIG. 5 is a graph showing an example of the thickness distribution of deposits on the upper electrode and the cover ring.

FIG. 6 is a graph showing a relationship between an etching rate and a position of the upper electrode in a radial direction thereof.

FIG. 7 is a graph showing a relationship between the etching rate and the position of the upper electrode in the radial direction thereof.

FIG. 8 is a graph showing a relationship between the etching rate and the position of the upper electrode in the radial direction thereof.

FIG. 9 is a graph showing a relationship between an etching rate and a position of a shield ring in a vertical direction thereof.

FIG. 10 is a graph showing a relationship between the etching rate and the position of the shield ring in the vertical direction thereof.

FIG. 11 is a graph showing an example of a differential waveform in EPD.

### DETAILED DESCRIPTION

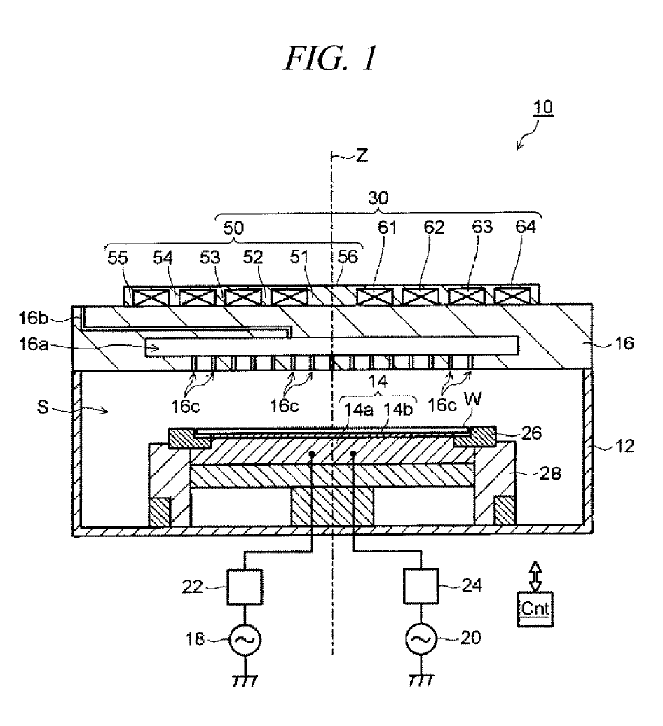

In the following, exemplary embodiments will be described in detail, and reference is made to the accompanying drawings, which form a part of the description. FIG. 1 is a cross sectional view schematically illustrating a configuration of a plasma processing apparatus according to an exemplary embodiment. The plasma processing apparatus 10 shown in FIG. 1 includes a hermetically sealed cylindrical processing chamber 12 configured to accommodate therein a semiconductor wafer W having a diameter of, e.g., 300 mm.

A circular plate-shaped mounting table 14 configured to mount the semiconductor wafer W thereon is provided in a lower portion of the processing chamber 12. The mounting table 14 includes a base 14a and an electrostatic chuck 14b. The base 14a is formed of a conductive member such as aluminum.

An annular focus ring 26 is provided on a peripheral region of a top surface of the base 14a to surround the semiconductor wafer W. Further, the electrostatic chuck 14b is provided on a central region of the top surface of the base 14a. The electrostatic chuck 14b has a circular plate shape, and includes an electrode film embedded in an insulating film. The electrostatic chuck 14b is configured to attract and hold the semiconductor wafer W as a processing target substrate with an electrostatic force generated by a DC voltage applied to the electrode film of the electrostatic chuck 14b from a DC power supply (not shown).

In the state that the semiconductor wafer W is mounted on the electrostatic chuck 14b, a central axis line Z that passes through a center of the semiconductor wafer W in a vertical direction substantially coincides with central axis lines of the base 14a and the electrostatic chuck 14b.

The base 14a constitutes a lower electrode. A first high frequency power supply 18 configured to generate a high frequency power for plasma generation is connected to the base 14a via a first matching device 22. The first high frequency power supply 18 generates a high frequency power having a frequency of, e.g., 100 MHz. The first matching device 22 is equipped with a circuit configured to match an output impedance of the first matching device 22 and an input impedance at a load side (lower electrode). Further, the first high frequency power supply 18 may be connected to the upper electrode 16.

In the present exemplary embodiment, the first high frequency power supply 18 is configured to apply the high frequency power for plasma generation in a pulse shape having a preset frequency (e.g., 90 kHz) and a preset duty ratio (e.g., 50%). Accordingly, there are provided a plasma generation period and a plasma non-generation period, and electric charges can be suppressed from being accumulated at a certain portion on the semiconductor wafer W. That is, during the plasma generation period, the electric charges may be accumulated at a portion where electron density is high since the electron density in the plasma is non-uniform. By providing the plasma non-generation period, however, the accumulated electric charges can be dispersed to the surrounding, so that the problem that the electric charges are accumulated can be resolved. Therefore, the insulating film or the like can be suppressed from being damaged.

Further, a second high frequency power supply 20 configured to generate a high frequency bias power for ion attraction is also connected to the base 14a via a second matching device 24. The second high frequency power supply 20 generates a high frequency power having a frequency (e.g., 3.2 MHz) lower than the frequency of the high frequency power from the first high frequency power supply 18. Further, the second matching device 24 includes a circuit configured to match an output impedance of the second matching device 24 and an input impedance at a load side (the lower electrode). Further, under the focus ring 26, a side surface of the mounting table 14 is surrounded by a shield ring 28.

An upper electrode 16 is provided above the mounting table (lower electrode) 14, facing the mounting table 14 with a processing space S therebetween. The upper electrode 16 has a circular plate shape and forms the processing space S while partitioning the processing space S from thereabove. The upper electrode 16 is disposed such that a central axis line thereof substantially coincides with the central axis line of the mounting table 14. In the present exemplary embodiment, a member which forms a surface of the upper electrode 16 facing the mounting table 14 is made of quartz. A non-illustrated cover ring is provided around the upper electrode 16 which is made of the quartz. Further, the material of the upper electrode 16 may not be limited to the quartz, and the upper electrode 16 may be made of silicon. Furthermore, a thermally sprayed film of a fluorine compound containing, by way of non-limiting example, yttrium oxide (Y₂O₃), or YF₃ may be formed on the surface of the upper electrode 16 facing the processing space S. In case that the upper electrode 16 is made of silicon, a DC voltage may be applied to the upper electrode 16.

The upper electrode 16 also has a function as a shower head configured to introduce a preset processing gas into the processing space S in a shower shape. In the present exemplary embodiment, the upper electrode 16 is provided with a buffer room 16a, a gas line 16b and a multiple number of gas holes 16c. The buffer room 16a is connected with one end of the gas line 16b. Further, the multiple number of gas holes 16c are connected to the buffer room 16a. The gas holes 16c are extended downwards and opened toward the processing space S. Meanwhile, a non-illustrated gas exhaust device such as a TMP (Turbo Molecular Pump) and a DP (Dry Pump) is connected to a bottom portion of the processing chamber 12 and is configured to maintain a pressure within the processing chamber 12 in a preset decompressed atmosphere.

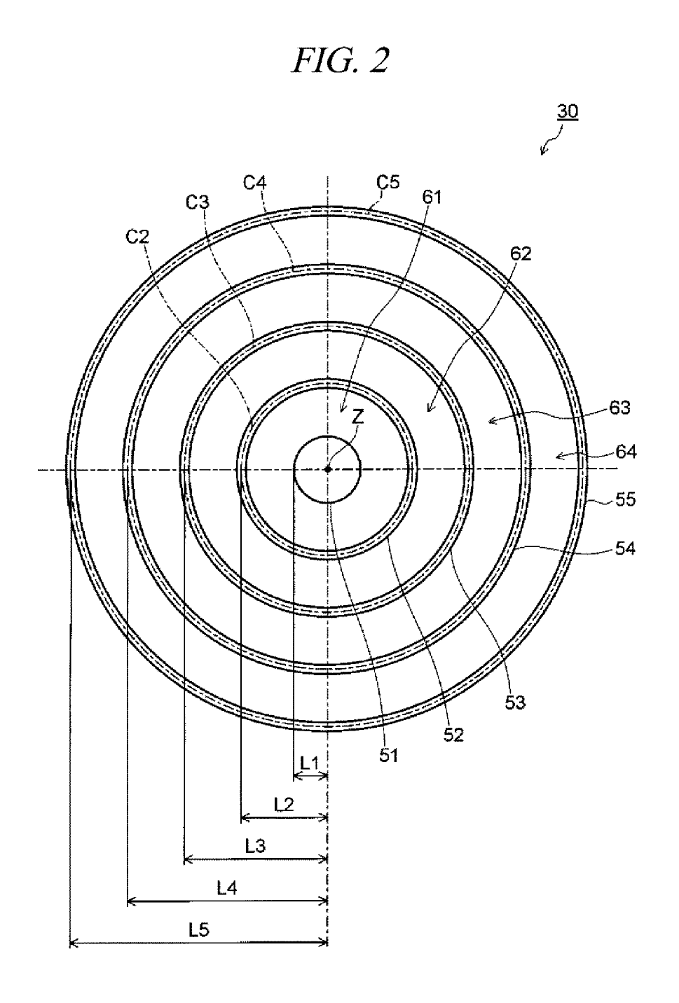

An electromagnet 30 is provided on the upper electrode 16. The electromagnet 30 includes a core member 50 and coils 61 to 64. The core member 50 has a structure in which a columnar portion 51, a plurality of cylindrical portions 52 to 55 and a base portion 56 are formed as a single body. The core member 50 is made of a magnetic material. The base portion 56 has a substantially circular plate shape, and a central axis line of the base portion 56 accords to the central axis line Z. The columnar portion 51 and the plurality of cylindrical portions 52 to 55 are protruded downwards from a bottom surface of the base portion 56. The columnar portion 51 has a substantially circular column shape, and a central axis line thereof accords to the central axis line Z. A radius L1 (see FIG. 2) of the columnar portion 51 is, for example, 30 mm.

Each of the cylindrical portions 52 to 55 has a cylindrical shape extended in the direction of the central axis line Z. As depicted in FIG. 2, the cylindrical portions 52 to 55 are respectively provided along a plurality of concentric circles C2 to C5 with respect to the central axis line Z. To elaborate, the cylindrical portion 52 is arranged along the concentric circle C2 having a radius L2 larger than the radius L1, and the cylindrical portion 53 is arranged along the concentric circle C3 having a radius L3 larger than the radius L2. The cylindrical portion 54 is arranged along the concentric circle C4 having a radius L4 larger than the radius L3, and the cylindrical portion 55 is arranged along the concentric circle C5 having a radius L5 larger than the radius L4.

As an example, the radii L2, L3, L4 and L5 are 76 mm, 127 mm, 178 mm and 229 mm, respectively. In this case, L4 and L5 are larger than the radius (150 mm) of the semiconductor wafer W. Accordingly, the coil 64 is positioned above the focus ring 26 which is located at an outside of the semiconductor wafer W. Further, center positions of the coils 61, 62, 63 and 64 are spaced apart from the central axis line Z by 50 mm, 100 mm, 150 mm and 200 mm, respectively.

A groove is formed between the columnar portion 51 and the cylindrical portion 52. As depicted in FIG. 1, the coil 61 wound along an outer surface of the columnar portion 51 is accommodated in the groove. Further, a groove is formed between the cylindrical portion 52 and the cylindrical portion 53, and the coil 62 wound along an outer surface of the cylindrical portion 52 is accommodated in this groove. Further, a groove is formed between the cylindrical portion 53 and the cylindrical portion 54, and the coil 63 wound along an outer surface of the cylindrical portion 53 is accommodated in this groove. Furthermore, a groove is formed between the cylindrical portion 54 and the cylindrical portion 55, and the coil 64 wound along an outer surface of the cylindrical portion 54 is accommodated in this groove. Both ends of each of the coils 61 to 64 are connected to a non-illustrated power supply. Supply and stop of the supply of an electric current to each of the coils 61 to 64, and a value of the electric current are controlled by a control signal from a controller Cnt.

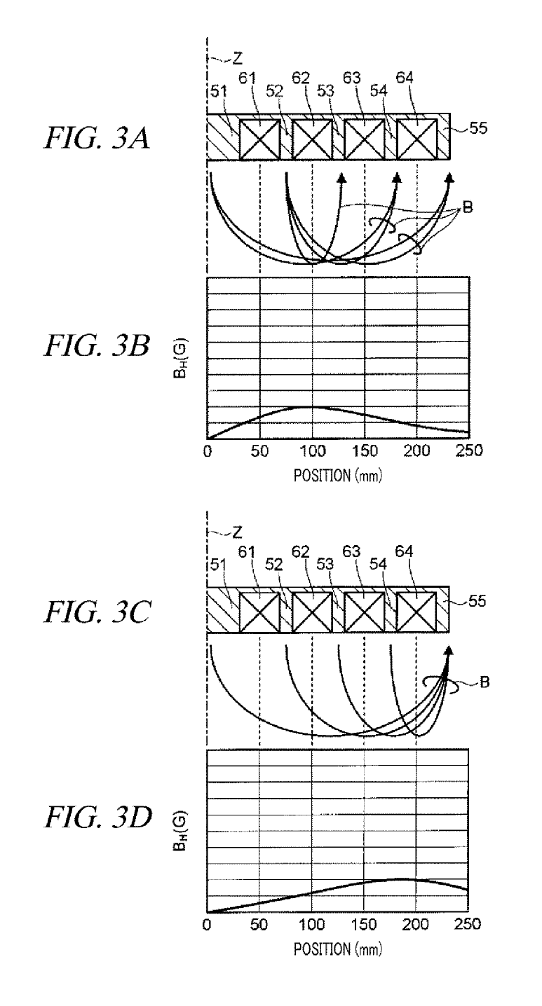

In the electromagnet 30 having the above-described configuration, by supplying an electric current to one or more of the coils 61 to 64, a magnetic field B having a horizontal magnetic field component B_{H} according to a radial direction with respect to the central axis line Z can be formed in the processing space S. FIG. 3A to FIG. 3D show examples of the magnetic fields formed by the electromagnet 30.

FIG. 3A illustrates a cross section of the electromagnet 30 on a half-plane with respect to the central axis line Z and a magnetic field B generated when an electric current is supplied to the coil 62. FIG. 3B depicts an intensity distribution of a horizontal magnetic field component B_{H} when the electric current is supplied to the coil 62.

Further, FIG. 3C shows the cross section of the electromagnet 30 on the half-plane with respect to the central axis line Z and a magnetic field B generated when an electric current is applied to the coil 64, and FIG. 3D depicts an intensity distribution of a horizontal magnetic field component B_{H} when the electric current is supplied to the coil 64. On graphs shown in FIG. 3B and FIG. 3D, a horizontal axis represents a position in the radial direction when a position of the central axis line Z is set to be 0 mm, and a vertical axis indicates an intensity (magnetic flux density) of the horizontal magnetic field component B_{H}.

If an electric current is supplied to the coil 62 of the electromagnet 30, the magnetic field B as shown in FIG. 3A is formed. This magnetic field B is oriented from end portions of the columnar portion 51 and the cylindrical portion 52 at the side of the processing space S toward end portions of the cylindrical portions 53 to 55 at the side of the processing space S. The intensity distribution of the horizontal magnetic field component B_{H} of the magnetic field B in the radial direction has a peak under a center of the coil 62, as shown in FIG. 3B. As an example, the position of the center of the coil 62 is about 100 mm away from the central axis line Z, and in case of processing the wafer W having a diameter of 300 mm, the center of the coil 62 is located above a midway position between a center and an edge of the wafer W.

Further, if an electric current is supplied to the coil 64 of the electromagnet 30, the magnetic field B as shown in FIG. 3C is formed. This magnetic field B is oriented from the end portions of the columnar portion 51 and the cylindrical portions 52 to 54 at the side of the processing space S toward the end portion of the cylindrical portion 55 at the side of the processing space S. The intensity distribution of the horizontal magnetic field component B_{H} of the magnetic field B in the radial direction has a peak under a center of the coil 64, as shown in FIG. 3D. As an example, the position of the center of the coil 64 is about 200 mm away from the central axis line Z, and in case of processing the wafer W having the diameter of 300 mm (radius of 150 mm), the center of the coil 64 is located above a position outside the edge of the wafer W in the radial direction, i.e., located at a position above the focus ring 26.

In the plasma processing apparatus 10, the processing gas from the gas supply system is supplied into the processing space S from the upper electrode 16 serving as the shower head, and the high frequency power from the first high frequency power supply 18 is supplied to the mounting table 14 serving as the lower electrode, so that the high frequency electric field is generated between the upper electrode 16 and the mounting table 14. Accordingly, plasma of the processing gas is generated in the processing space S. The semiconductor wafer W can be processed with active species of molecules or atoms constituting the processing gas dissociated in the plasma. Further, by adjusting the high frequency bias power applied from the second high frequency power supply 20 to the mounting table 14 serving as the lower electrode, it is possible to adjust the degree of ion attraction.

Further, the plasma processing apparatus 10 includes the controller Cnt. The controller Cnt is implemented by a programmable computer or the like. The controller Cnt controls the high frequency power supplied from the first high frequency power supply 18, the high frequency power supplied from the second high frequency power supply 20, a gas exhaust rate of the gas exhaust device, the kind of the gas supplied from the gas supply system and a flow rate thereof, and a value and a direction of the electric current supplied to the coils 61 to 64 of the electromagnet 30. To this end, the controller Cnt outputs control signals to the first high frequency power supply 18, the second high frequency power supply 20, the gas exhaust device, the individual constituent components of the gas supply system, the electric current source connected to the electromagnet 30 according to a recipe which is stored in a memory of the controller Cnt or inputted by an input device.

According to the exemplary embodiment, when performing a cleaning process of removing a deposit deposited on the upper electrode 16, by the controller Cnt, a cleaning gas is introduced into the processing chamber 12, and plasma of the cleaning gas is generated by applying the high frequency powers to the mounting table 14 as the lower electrode from the first high frequency power supply 18 and, when necessary, from the second high frequency power supply 20 as well. Further, by the controller Cnt, the magnetic field is generated by supplying the electric current to the coils 61 to 64 of the electromagnet 30, and the amount of the electric current supplied to each of the coils 61 to 64 is adjusted depending on a thickness distribution of the deposit on the upper electrode 16 in the radial direction.

In the plasma processing apparatus 10 having the above-described configuration, by disposing the focus ring 26 around the semiconductor wafer W, a plasma state around the outside of the semiconductor wafer W is made to be the same as a plasma state above the semiconductor wafer W, and a variation in an etching state at a peripheral portion of the semiconductor wafer W is suppressed. Therefore, processing uniformity over the surface of the semiconductor wafer W can be improved.

If a plasma etching process is performed on the semiconductor wafer W in the plasma processing apparatus 10, a deposit is deposited on an inner wall of the processing chamber 12, the quartz-made upper electrode 16, and so forth. Thus, the cleaning process is performed at a preset timing, for example, at a timing upon the lapse of a preset period during which the semiconductor wafer W is processed.

In this cleaning process, a preset cleaning gas (e.g., CF₄+O₂) is introduced into the processing chamber 12 through the upper electrode 16. Further, by applying the high frequency powers to the mounting table 14 as the lower electrode from the first high frequency power supply 18 and, when necessary, from the second high frequency power supply 20 as well, the cleaning gas is excited into plasma, and the deposit is removed with action of the plasma. Here, the thickness (amount) of the deposit deposited on the surface of the quartz-made upper electrode 16 facing the mounting table 14 may be differed depending on the positions on the upper electrode 16 in the radial direction.

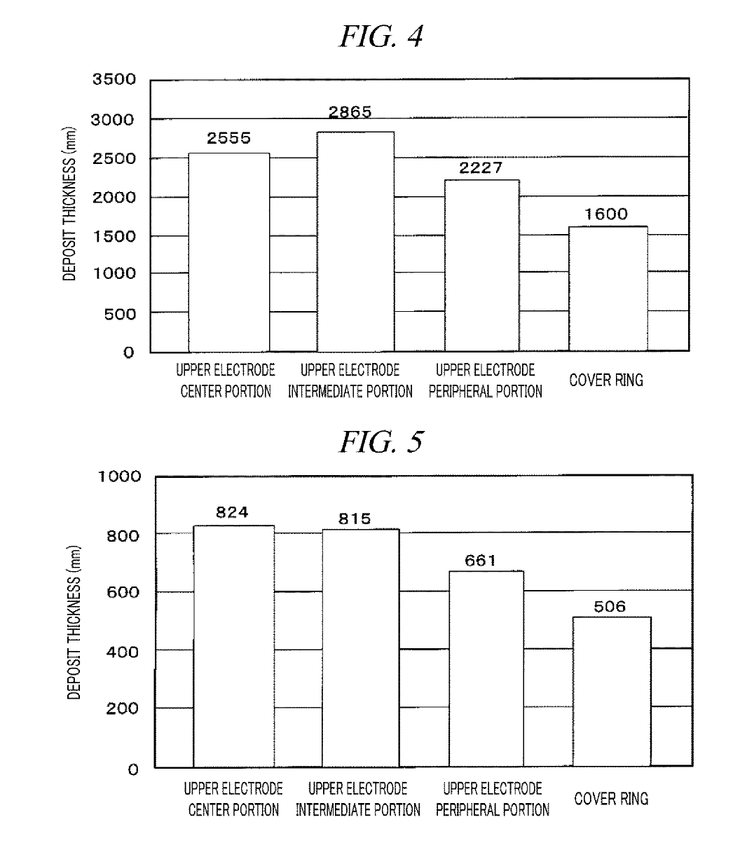

FIG. 4 and FIG. 5 show examples of the thickness of the deposit measured at positions distanced from the center of the upper electrode 16 by 0 mm (upper electrode center portion), 120 mm (upper electrode intermediate portion), 180 mm (upper electrode peripheral portion) and 240 mm (cover ring). In the example of FIG. 4, the thickness of the deposit is found to be 2555 nm, 2865 nm, 2227 nm and 1600 nm at the position where the distance from the center of the upper electrode 16 is 0 mm, 120 mm, 180 mm and 240 mm, respectively.

In the example of FIG. 5, the thickness of the deposit is found to be 824 nm, 815 nm, 661 nm and 506 nm at the position where the distance from the center of the upper electrode 16 is 0 mm, 120 mm, 180 mm and 240 mm, respectively.

As shown in FIG. 4 and FIG. 5, the thicknesses of the deposit deposited on the upper electrode 16 are not uniform and are different depending on the position in the radial direction. Further, a variation tendency of the thickness of the deposit is also different depending on the kind of the process to be performed. In the example of FIG. 4, the thickness of the deposit is thickest at the position where the distance from the center of the upper electrode 16 is 120 mm, and in the example of FIG. 5, the thickness of the deposit is thickest at the position where the distance from the center of the upper electrode 16 is 0 mm.

Further, FIG. 4 depicts a case of performing the plasma etching process by using a gas system composed of C₄F₈/HBr/SF₆, and FIG. 5 shows a case of performing the plasma etching process by using a gas system composed of CH₂F₂/HBr/NF₃.

As stated above, when the thicknesses of the deposit are different depending on the positions on the upper electrode 16 in the radial direction, if the cleaning process is performed at a uniform cleaning rate at each position, the upper electrode 16 would be first exposed at a portion where the thickness of the deposit is small. By continuously performing the cleaning process in this state, the deposit at a portion where the thickness of the deposit is large is removed. As a result, at the portion where the upper electrode 16 is first exposed, the upper electrode 16 is etched to be consumed.

According to the present exemplary embodiment, however, the cleaning process is performed in the state that the magnetic field is formed by flowing the electric current to each of the coils 61 to 64 of the electromagnet 30. Further, by adjusting a cleaning rate depending on the thickness of the deposit at each position on the upper electrode 16 in the radial direction, the state of the magnetic field is controlled such that the cleaning rate is relatively higher at the portion where the thickness of the deposit is large, whereas the cleaning rate is relatively lower at the portion where the thickness of the deposit is small.

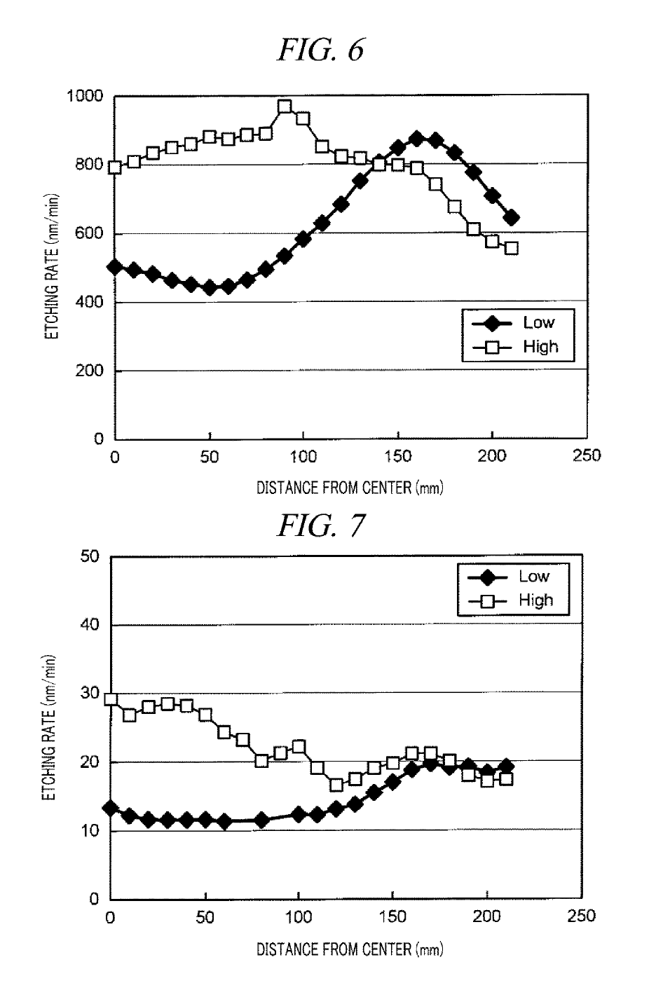

FIG. 6 and FIG. 7 show measurement results of an etching rate (cleaning rate) at each position on the upper electrode 16 in the radial direction when performing the cleaning process by using a gas system of CF₄/O₂=200 sccm/200 sccm as the cleaning gas under the conditions that the pressure is set to 26.6 Pa (200 mTorr), the high frequency power of the first high frequency power supply 18 is set to 2000 W and the high frequency power of the second high frequency power supply 20 is 150 W. In FIG. 6 and FIG. 7, a plot of black rhombus marks indicate a case (Low) where the magnetic field of 1 G is generated in each of the coils 61 to 64 of the electromagnet 30, and a plot of white square marks indicate a case (High) where the magnetic fields of 18 G/26 G/27 G/28 G are generated in the coils 61 to 64 of the electromagnet 30, respectively.

Further, FIG. 6 depicts a result of measuring an etching rate of a photoresist on the assumption that an organic-based deposit is formed, and FIG. 7 depicts a result of measuring an etching rate of a silicon oxide film on the assumption that a silicon-based deposit is formed. In the actual measurement, the cleaning process is performed after attaching a rectangular wafer chip having the photoresist film of a preset thickness formed and a rectangular wafer chip having the silicon oxide film of a preset thickness formed to each position of the upper electrode 16. Then, the etching rates are calculated by measuring residual film amounts of the rectangular wafer chips.

As can be seen from FIG. 6 and FIG. 7, if the cleaning process is performed in the state that a stronger magnetic field is formed by the coils 61 to 64 of the electromagnet 30, an overall etching rate (cleaning rate) is found to be increased for both the photoresist film and the silicon oxide film. Accordingly, a time required for the cleaning process can be shortened as compared to the conventional case, so that the productivity can be improved. Furthermore, the reason why the etching rate (cleaning rate) is increased may be because, if the magnetic field is formed, a residence time of electrons is lengthened so that a plasma density is increased.

In addition, in case of forming the stronger magnetic field by the coils 61 to 64 of the electromagnet 30, the etching rate (cleaning rate) at the central portion of the upper electrode tends to be increased, as compared to a case of forming the weaker magnetic field. Meanwhile, the etching rate (cleaning rate) at the peripheral portion of the upper electrode tends to be equal to or lower than that in case of forming the weaker magnetic field. As such, the etching rate (cleaning rate) at each position on the upper electrode 16 in the radial direction can be controlled by adjusting the intensity of the magnetic field formed by the coils 61 to 64 of the electromagnet 30.

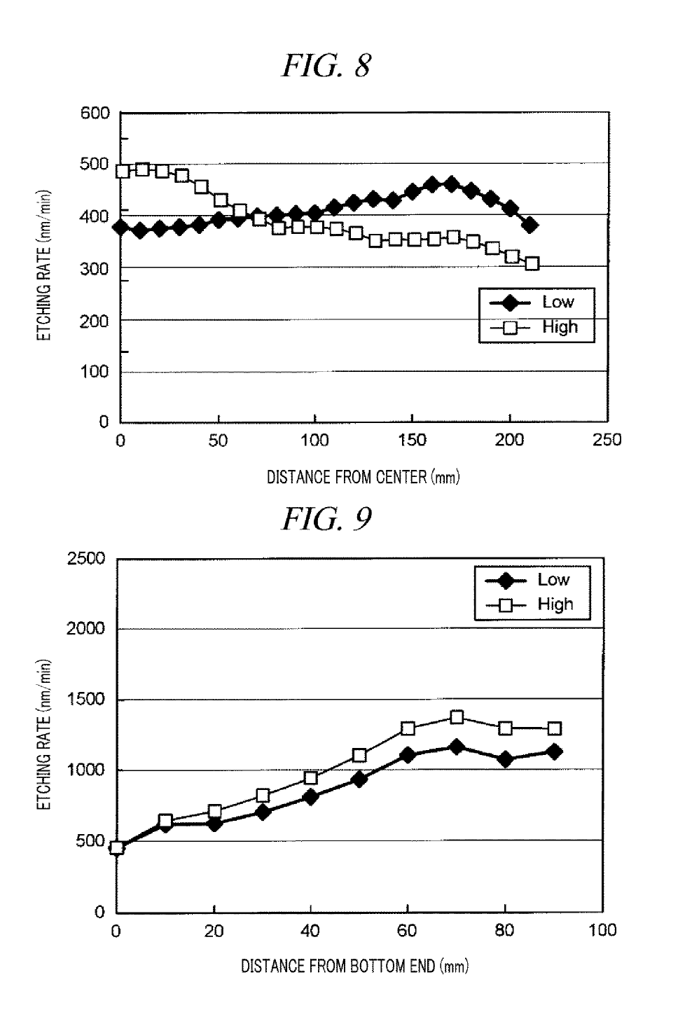

FIG. 8 provides a measurement result of an etching rate (cleaning rate) of the photoresist at each position on the upper electrode 16 in the radial direction when performing the cleaning process by using a gas system of O₂/He=950 sccm/900 sccm as the cleaning gas under the conditions that the pressure is set to 106.4 Pa (800 mTorr), the high frequency power of the first high frequency power supply 18 is set to 2000 W and the high frequency power of the second high frequency power supply 20 is 0 W. As can be seen from FIG. 8, the same tendency as observed in the case of FIG. 6 where the gas system of CF₄/O₂ is used as the cleaning gas is also observed in the case where the gas system of O₂/He is used as the cleaning gas.

Accordingly, the state of the magnetic field formed by the electromagnet 30 can be changed by adjusting the amount of the electric currents supplied to the respective coils 61 to 64 of the electromagnet 30. As a result, the etching rate (cleaning rate) can be controlled such that the etching rate (cleaning rate) is increased at the portion of the upper electrode 16 where the amount (thickness) of the deposit is large, whereas the etching rate (cleaning rate) is decreased at the portion of the upper electrode 16 where the amount (thickness) of the deposit is small. Therefore, at the portion where the amount (thickness) of the deposit is small, it is possible to suppress the surface of the upper electrode 16 from being exposed early before the cleaning process is completed, and, thus, it is also possible to suppress the upper electrode 16 from being etched to be worn out.

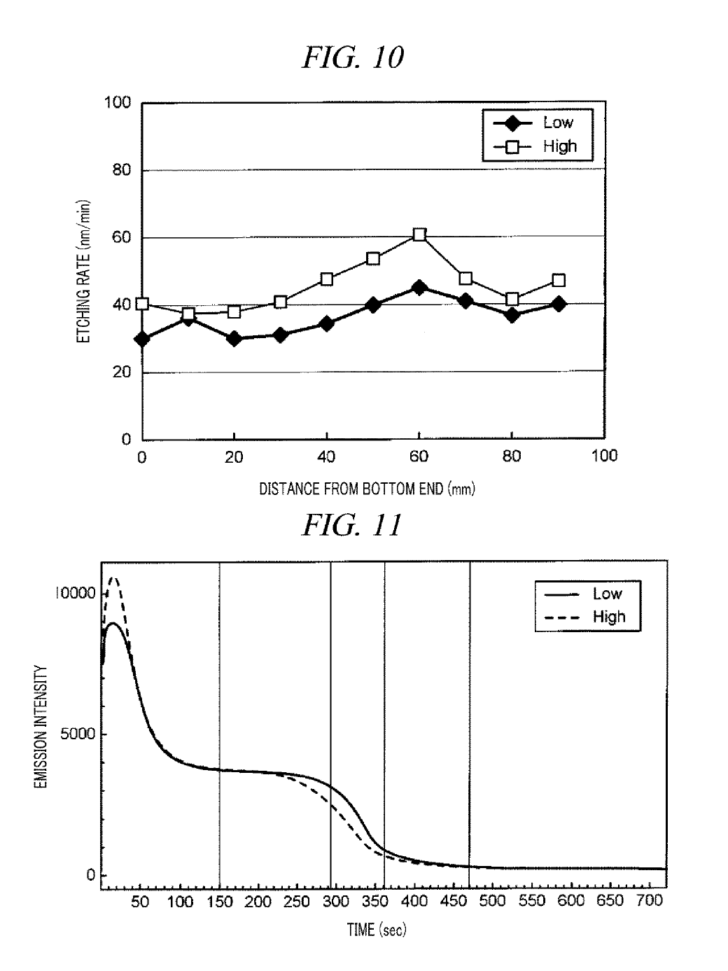

FIG. 9 and FIG. 10 show measurement results of an etching rate (cleaning rate) at each position on the shield ring 28 in the vertical direction when performing the vertical cleaning process by using a gas system of CF₄/O₂=200 sccm/200 sccm as the cleaning gas under the conditions that the pressure is set to 26.6 Pa (200 mTorr), the high frequency power of the first high frequency power supply 18 is set to 2000 W and the high frequency power of the second high frequency power supply 20 is 150 W. FIG. 9 depicts a result of measuring the etching rate of the photoresist on the assumption that an organic-based deposit is formed, and FIG. 10 depicts a result of measuring the etching rate of the silicon oxide film on the assumption that a silicon-based deposit is formed. Furthermore, as aforementioned, the shield ring is the member provided at the lateral side of the mounting table 14 shown in FIG. 1, and the etching rate (cleaning rate) is measured up to a position of 100 mm upwards from a bottom end of the shield ring which is set to be 0 mm. As can be seen from FIG. 9 and FIG. 10, by forming a stronger magnetic field, the etching rate (cleaning rate) at a certain portion of the shield ring 28 can be improved. Furthermore, a distribution of the etching rate (cleaning rate) at the shield ring 28 hardly changes depending on the variation in the intensity of the magnetic field.

FIG. 11 shows a result of measuring, by using an EPD (End Point Detector), a differential waveform of a wavelength of 440 nm (CO) during the cleaning process after processing a blanket wafer on which the photoresist as the carbon-based deposit is formed. A horizontal axis represents a time (sec) and a vertical axis represents an emission intensity. A solid line in the figure indicates a case (Low) where a magnetic field of 1 G is generated in each of the respective coils 61 to 64 of the electromagnet 30, and a dashed line indicates a case (High) where the magnetic fields of 18 G/26 G/27 G/28 G are generated in the coils 61 to 64 of the electromagnet 30, respectively. As depicted in FIG. 11, in case of generating the stronger magnetic fields, the differential waveform is found to be converged faster than in case of forming the weaker magnetic field, and, thus, the etching rate (cleaning rate) is found to be higher.

Here, it should be noted that the present exemplary embodiment is not limiting, and various changes and modifications may be made. By way of example, the cleaning gas is not limited to the aforementioned example of CF₄/O₂ or O₂/He, and various other gas systems such as NF₃/O₂ may be used.

### INDUSTRIAL APPLICABILITY

The cleaning method of the plasma processing apparatus and the plasma processing apparatus according to the present exemplary embodiments are applicable to the field of manufacture of semiconductor devices and thus have industrial applicability.

### EXPLANATION OF REFERENCE NUMERALS

10: Plasma etching device
12: Processing chamber
14: Mounting table
16: Upper electrode
18: First high frequency power supply
20: Second high frequency power supply
23: First matching device
24: Second matching device
26: Focus ring
30: Electromagnet
61˜64: Coils
Cnt: Controller
S: Processing space
W: Semiconductor wafer

1. A cleaning method of a plasma processing apparatus,
wherein the plasma processing apparatus comprises:
a processing chamber configured to accommodate a processing target substrate therein;
a lower electrode provided within the processing chamber and configured to mount the processing target substrate thereon;
an upper electrode, provided within the processing chamber, facing the lower electrode;
a high frequency power supply configured to apply a high frequency power between the upper electrode and the lower electrode; and
an electromagnet, provided on an upper portion of the processing chamber, including concentrically arranged annular coils, and
wherein the cleaning method, in which a deposit deposited on the upper electrode of the plasma processing apparatus is removed, comprises:
introducing a preset cleaning gas into the processing chamber and generating plasma of the preset cleaning gas by applying the high frequency power between the upper electrode and the lower electrode from the high frequency power supply; and
generating a magnetic field by supplying electric currents to the coils, and adjusting an amount of the electric current supplied to each of the coils individually depending on a distribution of a thickness of the deposit deposited on the upper electrode in a radial direction thereof.

2. The cleaning method of the plasma processing apparatus of claim 1,
wherein the number of the coils of the electromagnet is four, and the amount of the electric current supplied to each of the four coils is adjusted individually.

3. The cleaning method of the plasma processing apparatus of claim 1,
wherein the amount of the electric current supplied to each of the coils is individually adjusted such that a cleaning rate is high at a portion where the thickness of the deposit deposited on the upper electrode is relatively larger, whereas the cleaning rate is low at a portion where the thickness of the deposit deposited on the upper electrode is relatively smaller.

4. A plasma processing apparatus configured to process a processing target substrate with plasma, the plasma processing apparatus comprising:
a processing chamber configured to accommodate the processing target substrate therein;
a lower electrode provided within the processing chamber and configured to mount the processing target object thereon;
an upper electrode, provided within the processing chamber, facing the upper electrode;
a high frequency power supply configured to apply a high frequency power between the upper electrode and the lower electrode;
an electromagnet, provided on an upper portion of the processing chamber, including concentrically arranged annular coils; and
a controller configured to, when performing a cleaning process of removing a deposit deposited on the upper electrode, introduce a preset cleaning gas into the processing chamber; generate plasma of the preset cleaning gas by applying the high frequency power between the upper electrode and the lower electrode from the high frequency power supply; generate a magnetic field by supplying electric currents to the coils; and adjust an amount of the electric current supplied to each of the coils individually depending on a distribution of a thickness of a deposit deposited on the upper electrode in a radial direction thereof.

5. The plasma processing apparatus of claim 4,
wherein the number of the coils of the electromagnet is four, and the controller is configured to adjust the amount of the electric current supplied to each of the four coils individually.
